(19) United States
(12) Patent Application Publication
(10) Pub. No.: US 2023/0411532 A1
(43) Pub. Date: Dec. 21, 2023

(54) TFT DEVICE

(71) Applicant: TCL CHINA STAR OPTOELECTRONICS TECHNOLOGY CO., LTD., Shenzhen (CN)

(72) Inventor: Qunfang Liang, Shenzhen (CN)

(73) Assignee: TCL CHINA STAR OPTOELECTRONICS TECHNOLOGY CO., LTD., Shenzhen (CN)

(21) Appl. No.: 17/814,519

(22) Filed: Jul. 24, 2022

(30) Foreign Application Priority Data
Jun. 17, 2022 (CN) 202210693259.3

(51) Int. Cl. H01L 29/786

(52) U.S. Cl. CPC H01L 29/78696; H01L 29/78609

(57) ABSTRACT

A thin film transistor (TFT) device is provided. The TFT device includes a substrate, a semiconductor channel layer, an ohmic contact layer, and a source-drain layer that are sequentially arranged on one side of the substrate. In the channel region, a compensation pattern is disposed on a surface of the semiconductor channel layer away from the substrate. The compensation pattern and the semiconductor channel layer are different types of semiconductors. By disposing the compensation pattern on the surface of the semiconductor channel layer away from the substrate, the compensation pattern and the semiconductor channel layer are different types of semiconductors, the compensation pattern can further improve a conductivity of a PNP structure, or the compensation pattern can further reduce a leakage current of a NPN structure.

### CROSS REFERENCE TO RELATED APPLICATIONS

This application claims the priority of the Patent Application No. 202210693259.3 in China entitled as “TFT device”, filed on Jun. 17, 2022 to China Patent Office, which is hereby incorporated by reference in its entirety.

### FIELD OF DISCLOSURE

The present disclosure relates to the field of display technologies, and in particular, to a thin film transistor (TFT) device.

### BACKGROUND

Existing TFT devices do not select different types of semiconductor structures according to their different functions. For example, for a PNP type semiconductor structure, a gate needs to be turned off by applying a negative voltage, which will make a gate drive circuit very complicated, which not only increases a design cost, but also has additional power consumption. For an NPN type semiconductor structure, its conductivity is poor, and a current cannot flow from a source to a drain quickly.

Therefore, the existing TFT devices have technical problems of poor conductivity or large leakage current.

### SUMMARY OF DISCLOSURE

Embodiments of the present disclosure provide a TFT device, which can solve technical problems of poor conductivity or large leakage current in existing TFT devices.

An embodiment of the present disclosure provides a TFT device, including: a substrate, a semiconductor channel layer, an ohmic contact layer, a source-drain layer, and a compensation pattern.

The semiconductor channel layer is disposed on the substrate. The semiconductor channel layer includes a channel region, a first doped region, and a second doped region, and the first doped region and the second doped region are disposed on both sides of the channel region.

The ohmic contact layer is disposed on a surface of the semiconductor channel layer away from the substrate. The ohmic contact layer includes a first pattern attached to the first doped region and a second pattern attached to the second doped region.

The source-drain layer includes a source and a drain. The source is disposed on a surface of the first pattern away from the substrate, and the drain is disposed on a surface of the second pattern away from the substrate.

The compensation pattern is disposed on the surface of the semiconductor channel layer away from the substrate in the channel region. The compensation pattern and the semiconductor channel layer are different types of semiconductors, and the compensation pattern is a same type of semiconductor as the first pattern and the second pattern.

Alternatively, in some embodiments of the present disclosure, the semiconductor channel layer is a hole-type semiconductor, and the first pattern, the second pattern, and the compensation pattern are electron-type semiconductors.

Alternatively, in some embodiments of the present disclosure, the semiconductor channel layer is an electron-type semiconductor, and the first pattern, the second pattern, and the compensation pattern are hole-type semiconductors.

Alternatively, in some embodiments of the present disclosure, the compensation pattern, the first pattern, and the second pattern are arranged in a same layer.

Alternatively, in some embodiments of the present disclosure, a thickness of the compensation pattern, a thickness of the first pattern, and a thickness of the second pattern are equal.

Alternatively, in some embodiments of the present disclosure, a distance between the compensation pattern and the first pattern is equal to a distance between the compensation pattern and the second pattern.

Alternatively, in some embodiments of the present disclosure, the compensation pattern includes at least two sub-compensation patterns, and two adjacent sub-compensation patterns have a same thickness.

Alternatively, in some embodiments of the present disclosure, the sub-compensation patterns are uniformly arranged, and distances between adjacent sub-compensation patterns are equal.

Alternatively, in some embodiments of the present disclosure, in the channel region, a blocking member is disposed on a side of the semiconductor channel layer away from the substrate, and a resistance of a portion of the semiconductor channel layer overlapping with the blocking member in a thickness direction of film layers is lower than a resistance of a portion of the semiconductor channel layer staggered from the blocking member in the thickness direction of the film layers.

Alternatively, in some embodiments of the present disclosure, material of the compensation pattern includes at least one of amorphous silicon, phosphorus, and boron.

An embodiment of the present disclosure also provides a TFT device, including: a substrate, a semiconductor channel layer, an ohmic contact layer, a source-drain layer, and a compensation pattern. The semiconductor channel layer is disposed on the substrate. The semiconductor channel layer includes a channel region, a first doped region, and a second doped region. The ohmic contact layer includes a first pattern and a second pattern. The first pattern is disposed on the first doped region, and the second pattern is disposed on the second doped region. The source-drain layer is disposed on the ohmic contact layer. The compensation pattern is disposed on the channel region of the semiconductor channel layer. The semiconductor channel layer is a hole-type semiconductor, and the first pattern, the second pattern, and the compensation pattern are electron-type semiconductors; or the semiconductor channel layer is an electron-type semiconductor, and the first pattern, the second pattern, and the compensation pattern are hole-type semiconductors.

The details of one or more implementations are set forth in the accompanying drawings and the description below. Other features and advantages will be apparent from the description and drawings, and from the claims.

Beneficial effects are as follows. A normally-off TFT device has an NPN structure, and a normally-on TFT device has a PNP structure. Meanwhile, in the channel region, the surface of the semiconductor channel layer away from the substrate is provided with the compensation pattern. The compensation pattern and the semiconductor channel layer are different types of semiconductors. The compensation pattern is the same type of semiconductor as the first pattern and the second pattern. The compensation pattern can further improve a conductivity of the PNP structure, or the compensation pattern can further reduce a leakage current of the NPN structure.

### BRIEF DESCRIPTION OF DRAWINGS

In order to illustrate the technical solutions in the embodiments of the present disclosure more clearly, the following briefly introduces the accompanying drawings required for the description of the embodiments. Obviously, the drawings in the following description are only some examples of the present disclosure. For those skilled in the art, other drawings can also be obtained from these drawings without creative efforts.

FIG. 1 is a first schematic cross-sectional view of a TFT device of an embodiment of the present disclosure.

FIG. 2 is a second schematic cross-sectional view of a TFT device of an embodiment of the present disclosure.

FIG. 3 is a schematic cross-sectional view of an array substrate of an embodiment of the present disclosure.

### REFERENCE NUMERALS OF THE ACCOMPANYING DRAWINGS

10 substrate
30 gate insulating layer
50 ohmic contact layer
70 passivation layer
501 first pattern
503 compensation pattern
602 drain
H2 first doped region
90 blocking member
20 gate
40 semiconductor channel layer
60 source-drain layer
80 anode
502 second pattern
601 source
H1 channel region
H3 second doped region

### DETAILED DESCRIPTION

The technical solutions in the embodiments of the present disclosure will be clearly and completely described below with reference to the accompanying drawings in the embodiments of the present disclosure. Obviously, the described embodiments are only some, but not all, embodiments of the present disclosure. Based on the embodiments in the present disclosure, all other embodiments obtained by those skilled in the art without creative efforts shall fall within the protection scope of the present disclosure. Furthermore, it should be understood that the specific embodiments described herein are only used to illustrate and explain the present disclosure, and not to limit the present disclosure. In the present disclosure, unless stated to the contrary, the use of directional terms such as “upper” and “lower” generally refers to the upper and lower parts of the device in actual use or working state, specifically the direction of the drawing in the accompanying drawings; while “inner” and “outer” refer to the outline of the device.

For existing TFT devices, the TFT device with a PNP structure still has a problem of insufficient conductivity, and the TFT device with a NPN structure still has a problem of large leakage current.

Therefore, there is an urgent need to provide a TFT device that can solve the technical problems of poor conductivity or large leakage current of the existing TFT devices.

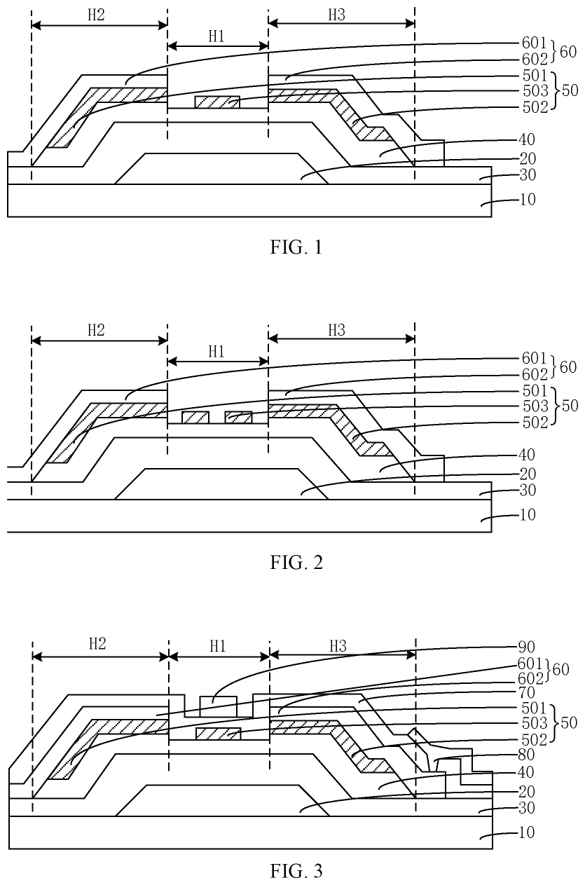

Referring to FIG. 1, the present disclosure provides a TFT device. The TFT device includes a substrate 10, a semiconductor channel layer 40, an ohmic contact layer 50, and a source-drain layer 60. The semiconductor channel layer 40 is disposed on the substrate 10. The semiconductor channel layer 40 includes a channel region H1, a first doped region H2, and a second doped region H3, and the first doped region H2 and the second doped region H3 are disposed on both sides of the channel region H1. The ohmic contact layer 50 is disposed on a surface of the semiconductor channel layer 40 away from the substrate 10. The ohmic contact layer includes a first pattern 501 attached to the first doped region H2 and a second pattern 502 attached to the second doped region H3. The source-drain layer 60 includes a source 601 and a drain 602. The source 601 is disposed on a surface of the first pattern 501 away from the substrate 10. The drain 602 is disposed on a surface of the second pattern 502 away from the substrate 10. In the channel region H1, a compensation pattern 503 is provided on the surface of the semiconductor channel layer 40 away from the substrate 10. The compensation pattern 503 and the semiconductor channel layer 40 are different types of semiconductors. The compensation pattern 503 is the same type of semiconductor as the first pattern 501 and the second pattern 502.

A gate 20 is also disposed on the substrate. A gate insulating layer 30 is also disposed on the side of the gate away from the substrate. The semiconductor channel layer 40 is disposed on a side of the gate insulating layer 30 away from the substrate 10.

The hole-type semiconductor is a P-type semiconductor, and the electron-type semiconductor is an N-type semiconductor.

It can be understood that the P-type semiconductor is connected with the N-type semiconductor to form a PN-junction. When an applied voltage causes a current to flow from the P-type semiconductor to the N-type semiconductor, the PN-junction has low resistance, so the current is large and the conductivity is good. On the contrary, when the applied voltage causes the current to flow from the N-type semiconductor to the P-type semiconductor, the PN-junction has high resistance and the leakage current is small. Therefore, in the channel region, by setting the compensation pattern on the surface of the semiconductor channel layer away from the substrate, the compensation pattern selects the N-type semiconductor or the P-type semiconductor according to the function of the TFT device, which can further differentiate the TFT device according to the function of normally-on or normally-off. That is, the conductivity of the normally-on TFT device is improved, or the leakage current of the normally-off TFT device is reduced to make it turn off more strictly.

It can be understood that, the normally-off TFT device is an NPN structure, and the normally-on TFT device is a PNP structure.

The NPN structure means that the semiconductor channel layer 40 is a P-type semiconductor, the first pattern 501 of the ohmic contact layer 50 in contact with the source 601 is an N-type semiconductor, and the second pattern 502 of the ohmic contact layer 50 in contact with the drain 602 is also an N-type semiconductor.

The PNP structure means that the semiconductor channel layer 40 is an N-type semiconductor, the first pattern 501 of the ohmic contact layer 50 in contact with the source 601 is a P-type semiconductor, and the second pattern 502 of the ohmic contact layer 50 and the drain 602 is also a P-type semiconductor.

In this embodiment, in the channel region H1, the surface of the semiconductor channel layer 40 away from the substrate 10 is further provided with the compensation pattern 503. The compensation pattern 503 and the semiconductor channel layer 40 are different types of semiconductors. The compensation pattern 503 is the same type of semiconductor as the first pattern 501 and the second pattern 502. The compensation pattern 503 can further improve the conductivity of the PNP structure, or the compensation pattern 503 can further reduce the leakage current of the NPN structure, such that the conductivity of the PNP structure TFT device is better, and the leakage current of the NPN structure TFT device is smaller.

The technical solutions of the present disclosure will now be described with reference to specific embodiments.

In one embodiment, the semiconductor channel layer 40 is a hole-type semiconductor, and the first pattern 501, the second pattern 502, and the compensation pattern 503 are electron-type semiconductors.

The semiconductor channel layer 40 is a hole-type semiconductor, the first pattern 501 and the second pattern 502 are electron-type semiconductor, and the TFT device can serve as a normally-off semiconductor device.

It is understandable that for the normally-off semiconductor devices, the leakage current needs to be reduced to make the turn-off stricter. It can be understood that, when a positive voltage V1 is applied to the gate 20, a first threshold voltage of the TFT device is Vth1. When V1>Vth1, a reverse channel will appear, so that current can flow from the source 601 to the drain 602, and the TFT device is turned on. However, due to the increase of the compensation pattern 503 of the hole-type semiconductor, it is equivalent to increase a PN junction of reverse high-resistance, which makes the threshold voltage of the TFT device larger. According to V1>Vth1, there will be a reverse channel. It can be known that: when Vth1 increases, the voltage V1 of the gate 20 required to turn on the TFT device is larger. Therefore, the TFT device with the NPN structure is turned off more strictly, and the leakage current is reduced.

In this embodiment, for the normally-off TFT device, the TFT device with the NPN structure is used. Meanwhile, in the channel region H1, the compensation pattern 503 with the N-type semiconductor is further disposed on the semiconductor channel layer 40 away from the substrate 10, which further increases the threshold voltage, makes the turn-off stricter, and reduces the leakage current.

In one embodiment, the semiconductor channel layer 40 is an electron-type semiconductor, and the first pattern 501, the second pattern 502, and the compensation pattern 503 are hole-type semiconductors.

The semiconductor channel layer 40 is an electron-type semiconductor, the first pattern 501 and the second pattern 502 are hole-type semiconductor, and the TFT device can serve as a normally-on semiconductor device.

It can be understood that, for the normally-on semiconductor devices, the conductivity of the TFT device needs to be improved, so that the current can be transmitted from the source 601 to the drain 602 more quickly.

It can be understood that when the gate 20 is supplied with a positive voltage V2, a second threshold voltage of the TFT device is Vth2. When V2>Vth2, a reverse channel will appear, so that current can flow from the source 601 to the drain 602, and the TFT device is turned on. However, due to the addition of the compensation pattern with the P-type semiconductor, it is equivalent to adding a PN-junction with forward low-resistance in the channel region, which makes the TFT device easier to turn on. That is, the threshold voltage of the TFT device is smaller, the voltage V2 of the gate 20 required to turn on the TFT device is smaller, and the on-channel current is higher, that is, the conductivity of the TFT device with the PNP structure is improved.

In this embodiment, for the normally-on TFT device, the PNP semiconductor structure is used. Meanwhile, in the channel region H1, the compensation pattern 503 with the P-type semiconductor is also disposed on the side of the semiconductor channel layer 40 away from the substrate 10, which further reduces the threshold voltage, reduces power consumption, and increases the on-channel current.

In an embodiment, the compensation pattern 503 is arranged at the same layer as the first pattern 501 and the second pattern 502.

Materials of the compensation pattern 503, the first pattern 501, and the second pattern 502 may be the same.

The compensation pattern 503, the first pattern 501, and the second pattern 502 may all be hole-type semiconductors, or may all be electron-type semiconductors.

It can be understood that the compensation pattern 503 and the first pattern 501 and the second pattern 502 are semiconductors of the same type, and therefore can be arranged in the same layer. Furthermore, the compensation pattern 503, the first pattern 501, and the second pattern 502 can be formed through one process, which can simplify the formation process and reduce the cost.

In this embodiment, by arranging the compensation pattern 503 and the first pattern 501 and the second pattern 502 in the same layer, the cost is further reduced.

In one embodiment, a thickness of the compensation pattern 503, a thickness of the first pattern 501, and a thickness of the second pattern 502 are equal.

The same thickness is convenient for the same process and the formation of the same material to obtain the compensation pattern 503, the first pattern 501, and the second pattern 502.

In one embodiment, a distance between the compensation pattern 503 and the first pattern 501 is equal to a distance between the compensation pattern 503 and the second pattern 502.

It can be understood that when only one compensation pattern 503 is set, distances between the compensation pattern 503 and the first pattern 501 and the second pattern 502 on both sides are equal, so that the PN-junction formed by the channel region H1 of the compensation pattern 503 has a more uniform influence on the TFT device, which can further improve the compensation performance of the compensation pattern 503.

In one embodiment, by increasing the thickness of the compensation pattern 503, the compensation performance of the compensation pattern 503 can be further improved.

Specifically, the thickness of the compensation pattern 503 is greater than the thickness of the first pattern 501 or the second pattern 502. For the NPN structure, by setting the compensation pattern 503 of the N-type semiconductor with a larger thickness, the leakage current of the TFT device can be further reduced. For the PNP structure, the conductivity of the TFT device can be further improved by setting the compensation pattern 503 of the P-type semiconductor with a larger thickness.

Referring to FIG. 2, in an embodiment, the compensation pattern 503 includes at least two sub-compensation patterns 503, and two adjacent sub-compensation patterns 503 have the same thickness.

Thicknesses of the adjacent sub-compensation patterns may be different. Furthermore, a plurality of sub-compensation patterns may be periodically arranged according to different thicknesses.

The compensation pattern 503 may include a first sub-compensation pattern 503, a second sub-compensation pattern 503, and a third sub-compensation pattern 503. Thicknesses of the first sub-compensation pattern 503, the second sub-compensation pattern 503, the third sub-compensation pattern 503, the first pattern 501, and the second pattern 502 are all equal.

It can be understood that the first pattern 501 and the second pattern 502 are used to lower the potential barrier between the source-drain layer 60 and the semiconductor channel layer 40, so that electrons can more easily enter the semiconductor channel layer 40 directly from the source-drain layer 60.

It can be understood that the equal thickness of the adjacent sub-compensation patterns 503 can further improve the uniformity of the compensation performance.

In this embodiment, the plurality of sub-compensation patterns 503 and the first pattern 501 and the second pattern 502 are formed in one process, which simplifies the process and reduces the cost.

Furthermore, in an embodiment, the sub-compensation patterns 503 are evenly arranged, and distances between adjacent sub-compensation patterns 503 are equal.

A distance between the first pattern 501 and the sub-compensation pattern 503 adjacent to the first pattern 501 is equal to a distance between two adjacent sub-compensation patterns 503.

A distance between the second pattern 502 and the sub-compensation pattern 503 adjacent to the second pattern 502 is equal to the distance two adjacent sub-compensation patterns 503.

In this embodiment, by arranging the sub-compensation patterns 503, the first pattern 501, and the second pattern 502 at an equal distance, the uniformity of the compensation pattern 503 for conductivity or turn-off is further improved.

In an embodiment, in the channel region H1, a blocking member 90 is disposed on a side of the semiconductor channel layer 40 away from the substrate 10. A resistance of a portion of the semiconductor channel layer 40 overlapping with the blocking member 90 in a thickness direction of film layers is lower than a resistance of a portion of the semiconductor channel layer 40 staggered from the blocking member 90 in the thickness direction of the film layers.

An impedance of a portion of the semiconductor channel layer 40 in a conductor state is lower than that of the other portions of the semiconductor channel layer 40 in a semiconductor state, which can reduce the impedance of the whole semiconductor channel layer 40.

In this embodiment, by disposing the blocking member 90 on the side of the semiconductor channel layer 40 away from the substrate 10, a dark state current of the TFT device is reduced, and a sensitivity of the TFT device is improved.

In one embodiment, the blocking member 90 may have a ring structure.

In a thickness direction of the substrate, a cross-sectional shape of the blocking member may be annular.

It can be understood that the portion of the semiconductor channel layer 40 in the conductor state corresponding to the blocking member 90 also has the ring structure. This portion overlaps with the blocking member 90 in the thickness direction of the film layers.

In an embodiment, material of the compensation pattern 503 includes at least one of amorphous silicon, phosphorus, and boron.

Material of the P-type semiconductor includes amorphous silicon and boron, and material of the N-type semiconductor includes amorphous silicon and phosphorus. In terms of technology, if boron is doped into the amorphous silicon semiconductor material, the semiconductor is a P-type semiconductor, and if phosphorus is doped into the amorphous silicon semiconductor material, the semiconductor is an N-type semiconductor.

In the above-mentioned embodiments, an ultimate purpose is to realize the separation of normally-on and normally-off functions of the TFT device, and to enhance the effective use of the TFT device. It is understandable that the NPN structure is used in fields that require normally-off semiconductor device applications. By setting the compensation pattern 503 of the N-type semiconductor, the leakage current of the NPN structure can be further reduced. The PNP structure is used in fields that require normally-on semiconductor device applications. The compensation pattern 503 of the N-type semiconductor is arranged to further enhance the conductivity of the PNP structure.

In one embodiment, a contact area between the compensation pattern 503 and the semiconductor channel layer 40 is greater than a contact area between the first pattern 501 and the semiconductor channel layer 40.

In one embodiment, a contact area between the compensation pattern 503 and the semiconductor channel layer 40 is greater than a contact area between the second pattern 502 and the semiconductor channel layer 40.

It can be understood that by increasing the contact area between the compensation pattern 503 and the semiconductor channel layer 40, the compensation performance of the compensation pattern 503 is further improved. For the N-type semiconductor compensation pattern 503, the larger the contact area between the N-type semiconductor compensation pattern 503 and the semiconductor channel layer 40, the smaller the leakage current of the TFT device. For the P-type semiconductor compensation pattern 503, the larger the contact area between the P-type semiconductor compensation pattern 503 and the semiconductor channel layer 40, the better the conductivity of the TFT device.

Referring to FIG. 3, the present disclosure also provides an array substrate. The array substrate includes the above-mentioned TFT device. The array substrate also includes a passivation layer and anode 80. The passivation layer is disposed on aside of the TFT device away from the substrate 10. The anode 80 is disposed on a side of the passivation layer 70 away from the substrate 10. The anode 80 is connected to the source 601 through a via hole extending through the passivation layer 70.

It should be noted that the array substrate includes a plurality of TFT devices. According to the required function of the TFT device, the TFT device with the NPN structure or the TFT device with the PNP structure is selected. By setting the corresponding compensation pattern, the TFT device can further reduce the leakage current of the TFT device or improve the conductivity of the TFT device.

The present disclosure also provides a display panel, a display module, and a display device. The display panel, the display module, and the display device all include the above-mentioned TFT device or array substrate, which will not be repeated here.

The TFT device of the embodiments includes the substrate, the semiconductor channel layer, the ohmic contact layer, and the source-drain layer. The semiconductor channel layer is disposed on the substrate. The semiconductor channel layer includes the channel region, the first doped region, and the second doped region, and the first doped region and the second doped region are disposed on both sides of the channel region. The ohmic contact layer is disposed on the surface of the semiconductor channel layer away from the substrate. The ohmic contact layer includes the first pattern attached to the first doped region and the second pattern attached to the second doped region. The source-drain layer includes the source and the drain. The source is disposed on the surface of the first pattern away from the substrate, and the drain is disposed on the surface of the second pattern away from the substrate. The compensation pattern is disposed on the surface of the semiconductor channel layer away from the substrate in the channel region. The compensation pattern and the semiconductor channel layer are different types of semiconductors, and the compensation pattern is a same type of semiconductor as the first pattern and the second pattern. The normally-off TFT device has the NPN structure, and the normally-on TFT device has the PNP structure. Setting the corresponding compensation pattern can further improve the conductivity of the PNP structure, or the compensation pattern can further reduce the leakage current of the NPN structure.

It should be noted that the corresponding compensation pattern refers to that the compensation pattern and the semiconductor channel layer are different types of semiconductors, and the compensation pattern is the same type of semiconductor as the first pattern and the second pattern. Therefore, for the NPN structure, the compensation pattern is unique, that is, the compensation pattern is the N-type semiconductor. For the PNP structure, the compensation pattern is also unique, that is, the compensation pattern is the P-type semiconductor.

In the above-mentioned embodiments, the description of each embodiment has its own emphasis. For parts that are not described in detail in a certain embodiment, reference may be made to the relevant descriptions of other embodiments.

The TFT device and the array substrate provided by the embodiments of the present disclosure have been introduced in detail above. The principles and implementations of the present disclosure are explained with specific examples in this specification. The descriptions of the above embodiments are only used to help understand the method and the core idea of the present disclosure. Meanwhile, for those skilled in the art, according to the idea of the present disclosure, there will be changes in the specific implementation manner and application scope. In conclusion, the content of this specification should not be construed as a limitation on the present disclosure.

What is claimed is:

1. A thin film transistor (TFT) device, comprising:
a substrate;
a semiconductor channel layer disposed on the substrate, wherein the semiconductor channel layer comprises a channel region, a first doped region, and a second doped region, and the first doped region and the second doped region are disposed on both sides of the channel region;
an ohmic contact layer disposed on a surface of the semiconductor channel layer away from the substrate, wherein the ohmic contact layer comprises a first pattern attached to the first doped region and a second pattern attached to the second doped region;
a source-drain layer comprising a source and a drain, wherein the source is disposed on a surface of the first pattern away from the substrate, and the drain is disposed on a surface of the second pattern away from the substrate; and
a compensation pattern disposed on the surface of the semiconductor channel layer away from the substrate in the channel region, wherein the compensation pattern and the semiconductor channel layer are different types of semiconductors, and the compensation pattern is a same type of semiconductor as the first pattern and the second pattern.

2. The TFT device according to claim 1, wherein the semiconductor channel layer is a hole-type semiconductor, and the first pattern, the second pattern, and the compensation pattern are electron-type semiconductors.

3. The TFT device according to claim 1, wherein the semiconductor channel layer is an electron-type semiconductor, and the first pattern, the second pattern, and the compensation pattern are hole-type semiconductors.

4. The TFT device according to claim 2, wherein the compensation pattern, the first pattern, and the second pattern are arranged in a same layer.

5. The TFT device according to claim 4, wherein a thickness of the compensation pattern, a thickness of the first pattern, and a thickness of the second pattern are equal.

6. The TFT device according to claim 5, wherein a distance between the compensation pattern and the first pattern is equal to a distance between the compensation pattern and the second pattern.

7. The TFT device according to claim 4, wherein the compensation pattern comprises at least two sub-compensation patterns, and two adjacent sub-compensation patterns have a same thickness.

8. The TFT device according to claim 7, wherein the sub-compensation patterns are uniformly arranged, and distances between adjacent sub-compensation patterns are equal.

9. The TFT device according to claim 1, wherein in the channel region, a blocking member is disposed on a side of the semiconductor channel layer away from the substrate, and a resistance of a portion of the semiconductor channel layer overlapping with the blocking member in a thickness direction of film layers is lower than a resistance of a portion of the semiconductor channel layer staggered from the blocking member in the thickness direction of the film layers.

10. The TFT device according to claim 1, wherein material of the compensation pattern comprises at least one of amorphous silicon, phosphorus, and boron.

11. A thin film transistor (TFT) device, comprising:
a substrate;
a semiconductor channel layer disposed on the substrate, wherein the semiconductor channel layer comprises a channel region, a first doped region, and a second doped region;
an ohmic contact layer comprising a first pattern and a second pattern, wherein the first pattern is disposed on the first doped region, and the second pattern is disposed on the second doped region;
a source-drain layer disposed on the ohmic contact layer; and
a compensation pattern disposed on the channel region of the semiconductor channel layer;
wherein the semiconductor channel layer is a hole-type semiconductor, and the first pattern, the second pattern, and the compensation pattern are electron-type semiconductors; or
wherein the semiconductor channel layer is an electron-type semiconductor, and the first pattern, the second pattern, and the compensation pattern are hole-type semiconductors.

12. The TFT device according to claim 11, wherein the compensation pattern, the first pattern, and the second pattern are arranged in a same layer.

13. The TFT device according to claim 11, wherein a thickness of the compensation pattern, a thickness of the first pattern, and a thickness of the second pattern are equal.

14. The TFT device according to claim 11, wherein a distance between the compensation pattern and the first pattern is equal to a distance between the compensation pattern and the second pattern.

15. The TFT device according to claim 11, wherein the compensation pattern comprises at least two sub-compensation patterns, and two adjacent sub-compensation patterns have a same thickness.

16. The TFT device according to claim 15, wherein the sub-compensation patterns are uniformly arranged, and distances between adjacent sub-compensation patterns are equal.

17. The TFT device according to claim 11, wherein in the channel region, a blocking member is disposed on a side of the semiconductor channel layer away from the substrate, and a resistance of a portion of the semiconductor channel layer overlapping with the blocking member in a thickness direction of film layers is lower than a resistance of a portion of the semiconductor channel layer staggered from the blocking member in the thickness direction of the film layers.

18. The TFT device according to claim 11, wherein material of the compensation pattern comprises at least one of amorphous silicon, phosphorus, and boron.
